(19) United States
(12) Patent Application Publication
(10) Pub. No.: US 2008/0231360 A1
(43) Pub. Date: Sep. 25, 2008

(54) ARRANGEMENT OF SIGNAL LINE PAIRS AND AMPLIFIERS

(75) Inventors: Alberto Milia, Dresden (DE); Helmut Schneider, Muenchen (DE); Joerg Schreiter, Markkleeberg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 12/051,284

(22) Filed: Mar. 19, 2008

(30) Foreign Application Priority Data
Mar. 19, 2007 (DE) 10 2007 012 902.7

(51) Int. Cl. H03F 3/04

(52) U.S. Cl. 330/250

(57) ABSTRACT

An arrangement of signal line pairs and amplifiers is disclosed. One embodiment provides each signal line pair of a group of signal line pairs that are directly adjacent and run parallel to one another is respectively assigned an amplifier from a group of amplifiers arranged successively in a signal line direction. Each signal line pair includes a first and a second signal line, between which the amplifier assigned to the respective signal line pair is arranged. The position of an amplifier is assigned to a specific signal line pair in the amplifier group along the signal line direction is chosen in such a way that a first coupling section which forms the first signal line assigned to the respective amplifier together with its adjacent lines along the amplifier group, and a second coupling section, which forms the second signal line assigned to the respective amplifier together with its adjacent lines along the amplifier group, substantially have the same coupling properties.

### CROSS-REFERENCE TO RELATED APPLICATIONS

This Utility Patent Application claims priority to German Patent Application No. DE 10 2007 012 902.7 filed on Mar. 19, 2007, which is incorporated herein by reference.

### BACKGROUND

Electronic circuits such as semiconductor circuits, for example, use during operation electrical signals which are generally manifested in the form of a temporal development of the electrical voltage on their internal conductor structures. Depending on the type of circuit, the voltage profile of the signals must in this case satisfy specific specifications in order to ensure the interaction of the individual circuit parts. An excessively great deviation of the signals of specific circuit parts from the setpoint stipulation, e.g., owing to interference signals occurring on the respective circuit parts, can lead to a faulty behavior of the entire semiconductor circuit. Besides various interference factors acting on the semiconductor circuit and its signals from outside, primarily internal interference factors caused by the reciprocal capacitive influencing of the circuit parts can also be responsible for the occurrence of such interference signals. In general, in the case of an internal interference, the electrical potential of an affected interconnect is altered in an undesirable manner by interference signals coupled in capacitively from an adjacent circuit part, such as e.g., an adjacent interconnect (aggressor line) or amplifier circuit. Such parasitic coupling effects occur to an increased extent in the case of interconnects arranged at a very small distance alongside one another. Therefore, the coupling effects can drastically increase as feature sizes become smaller and smaller.

Apart from the structural features of the conductor structures or circuit parts involved, the magnitude of an interference signal occurring on an interconnect depends, for example, on the present signal level or signal level swing on the adjacent aggressor circuit part. Therefore, the interference signal component coupled in generally exhibits a proportional behavior with respect to the signal or signal level swing of the aggressor circuit part.

Such coupled-in interference signals can have a particularly interfering effect in the case of signal lines which have only a relatively weak signal during operation of the semiconductor circuit or for which only very small deviations of the electrical potential are permitted during operation. Such signal lines occur in modem memory devices, for example, where, on account of the high integration density, a multiplicity of memory cells together with associated bit and word lines and also sense amplifiers are realized in an extremely confined space. One such memory device is a dynamic random access memory (DRAM) for example. In this type of memory information units in the form of specific charges are stored in specific memory cells each including a storage capacitor. During the read-out of an information unit, the respective storage capacitor is connected to the associated bit line. As a result of a charge transfer from the storage capacitor onto the bit line, the electrical potential of the bit line experiences a displacement whose direction depends on the respective charge state of the memory cell capacitor and thus on the stored information. In order to determine it, a specific sense amplifier compares the electrical potential of the bit line with a constant electrical potential of a reference bit line. On account of the relatively small capacitance which a storage capacitor represents in relation to the bit line, the potential displacement on the bit line and therefore the potential difference to be detected between the respective bit line and its reference line turns out to be only very small. This makes the DRAM memory particularly sensitive to interference signals coupled in asymmetrically onto the two bit lines of a complementary bit line pair. This is because a potential difference caused by an asymmetrical coupling in on the bit lines of a bit line pair has to be compensated for by the charge of the storage capacitor. For approximately half of all cases, this results in a reduced signal margin between the low state and the high state on the bit line. However, such a reduction of the signal margin can have the consequence that the information read out can no longer be interpreted unambiguously by the evaluation circuit responsible for this. The asymmetrical or unbalanced interference signal coupling-in thus leads to the reduction of the signal margin budget of the dynamic memory. Furthermore, the sensing time can also be prolonged by the asymmetrical coupling. The degradation of the sensing time ultimately leads to a lower access speed of the memory. Likewise, further properties of the memory device, such as e.g., its reliability, can also be adversely influenced by the unbalanced interference signal coupling-in on the bit line pairs.

In order to ensure the data integrity guaranteed by the manufacturer, it must be ensured that the coupled-in interference signals cannot lead to corruptions of the potential difference of the useful signal on the complementary bit line pair during regular operation. This can be done, for example, by increasing the potential difference between the high state and the low state, for instance by increasing the ratio between the memory cell capacitance and the bit line capacitance in favor of the memory cell capacitance. This is because a larger memory cell capacitance causes a higher signal margin between the logic states on the respective bit line. Unbalanced interference signals can be better compensated for by this means. However, the magnitude of the memory cell capacitance is generally directly associated with the space requirement of the respective storage capacitor or the complexity of the design and thus also of the memory cell itself, which leads inevitably to an undesirable limitation of the memory density.

Generally, the interference signal components coupled in on lines can be reduced furthermore in favor of the useful signal component by adapting the design of the relevant lines. Thus, the coupling properties of the bit lines running in the memory cell array can be positively influenced, e.g., with the aid of relatively short word and bit lines, twisted bit lines (twisted bit line concept) or suitable shielding measures between the bit lines. However, these measures, too, are generally associated with a greater area requirement. Moreover, these measures specifically designed for reducing the interference signal coupling-in in the cell array are not suitable for reducing instances of asymmetrical interference signal coupling-in on the bit lines which are caused in the region of the sense amplifiers. This relates both to instances of interference signal coupling-in which are caused by reciprocal influencing of the bit lines running particularly closely alongside one another in this region, and to those instances which are caused by the sense amplifiers themselves.

### SUMMARY

On aspect provides an arrangement of signal line pairs and amplifiers in which each signal line pair of a group of signal line pairs that are directly adjacent and run parallel to one another is respectively assigned an amplifier from a group of amplifiers arranged successively in a signal line direction, the amplifier extending perpendicular to the signal line direction over a plurality of signal line pairs of the signal line pair group. In this case, each signal line pair includes a first and a second signal line between which the amplifier assigned to the respective signal line pair is arranged, wherein the amplifier amplifies a difference in the electrical potentials on the two signal lines. It is provided that the position of an amplifier assigned to a specific signal line pair in the amplifier group along the signal line direction is chosen in such a way that a first coupling section which forms the first signal line assigned to the respective amplifier together with its adjacent lines along the amplifier group, and a second coupling section, which forms the second signal line assigned to the respective amplifier together with its adjacent lines along the amplifier group, substantially have the same coupling properties.

One aspect further provides an integrated circuit including an arrangement of signal line pairs and amplifiers in which each signal line pair of a group of signal line pairs that are directly adjacent and run parallel to one another is respectively assigned an amplifier from a group of amplifiers arranged successively in a signal line direction, the amplifier extending perpendicular to the signal line direction over a plurality of signal line pairs of the signal line pair group. In this case, each signal line pair includes a first and a second signal line between which the amplifier assigned to the respective signal line pair is arranged, wherein the amplifier amplifies a difference in the electrical potentials on the two signal lines. It is provided that the position of an amplifier assigned to a specific signal line pair in the amplifier group along the signal line direction is chosen in such a way that a first coupling section which forms the first signal line assigned to the respective amplifier together with its adjacent lines along the amplifier group, and a second coupling section, which forms the second signal line assigned to the respective amplifier together with its adjacent lines along the amplifier group, substantially have the same coupling properties.

One aspect further provides a system such as a computer system, for example, including a circuit board and a memory device arranged on the circuit board and having an arrangement of signal line pairs and amplifiers in which each signal line pair of a group of signal line pairs that are directly adjacent and run parallel to one another is respectively assigned an amplifier from a group of amplifiers arranged successively in a signal line direction, the amplifier extending perpendicular to the signal line direction over a plurality of signal line pairs of the signal line pair group. In this case, each signal line pair includes a first and a second signal line between which the amplifier assigned to the respective signal line pair is arranged, wherein the amplifier amplifies a difference in the electrical potentials on the two signal lines. It is provided that the position of an amplifier assigned to a specific signal line pair in the amplifier group along the signal line direction is chosen in such a way that a first coupling section which forms the first signal line assigned to the respective amplifier together with its adjacent lines along the amplifier group, and a second coupling section, which forms the second signal line assigned to the respective amplifier together with its adjacent lines along the amplifier group, substantially have the same coupling properties.

One aspect furthermore provides a method for optimizing a connection scheme of an arrangement of signal line pairs and assigned amplifiers, in which each signal line pair of a signal line pair group is respectively assigned an amplifier of an amplifier group in order to amplify a difference in the electrical potentials on a first and a second signal line of the respective signal line pair. In this case, the position of the amplifier arranged between the two signal lines of the respective signal line pair in the amplifier group along the signal line direction is chosen in such a way that the coupling sections forming the two signal lines of the respective signal line pair together with their respectively adjacent lines along the amplifier group substantially have the same coupling properties.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates an arrangement with a connecting scheme of bit line pairs and associated sense amplifiers.

FIG. 2 illustrates a further arrangement with an optimized connecting scheme of bit line pairs and associated sense amplifiers.

FIG. 3 illustrates a further arrangement with an optimized connecting scheme of bit line pairs and associated sense amplifiers.

FIG. 4 illustrates a further arrangement with an optimized connecting scheme of bit line pairs and associated sense amplifiers.

FIG. 5 illustrates a yet another arrangement with an optimized connecting scheme of bit line pairs and associated sense amplifiers.

FIG. 6 illustrates a system such as a computer system, for example, including a circuit board and a memory device arranged on the circuit board and having an arrangement with an optimized connecting scheme of bit line pairs and associated sense amplifiers.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

The following embodiments relate to an arrangement including a group of signal line pairs running alongside one another and a group of amplifiers which are respectively assigned to one of the signal line pairs in order to amplify differences in the electrical potentials on the two signal lines of the respective signal line pair. In this case, provision is made for optimizing the connection configuration between the signal lines and the associated amplifier in such a way that a coupling in of interference signals on the two signal lines of a pair takes place as uniformly as possible for all of the signal line pairs. Further embodiments relate to a method for optimizing the connection configuration between the signal line pairs and the amplifiers.

In an arrangement of signal line pairs and amplifiers each signal line pair of a group of signal line pairs that are directly adjacent and run parallel to one another is respectively assigned an amplifier from a group of amplifiers arranged successively in a signal line direction, the amplifier extending perpendicular to the signal line direction over a plurality of signal line pairs of the signal line pair group. In this case, each signal line pair includes a first and a second signal line between which the amplifier assigned to the respective signal line pair is arranged, wherein the amplifier amplifies a difference in the electrical potentials on the two signal lines. It is provided that the position of an amplifier assigned to a specific signal line pair in the amplifier group along the signal line direction is chosen in such a way that a first coupling section which forms the first signal line assigned to the respective amplifier together with its adjacent lines along the amplifier group, and a second coupling section, which forms the second signal line assigned to the respective amplifier together with its adjacent lines along the amplifier group, substantially have the same coupling properties. This arrangement permits substantially the same interference signals to be coupled in on the two signal lines of a signal line pair. The associated improved coupling symmetry of the signal line pair reduces the corruption of the useful signal appearing as a potential difference on the two signal lines during operation. Particularly in the case of memory devices in which a sense amplifier detects an information unit on the basis of a relatively small potential difference between two complementary bit lines, the potential difference required for reliably identifying the information can be reduced with the aid of the arrangement described here. Consequently, in dynamic memory devices it is possible to reduce the storage capacitances of the memory cells without a higher error rate or a reduced yield occurring. As an alternative, a higher yield in the production of the memory device is also possible with the aid of embodiments.

In one embodiment, the position of each of the amplifiers in the amplifier group along the signal line direction is chosen in such a way that the degree of deviation between the coupling properties of the first and the second coupling sections of a signal line pair assigned to an amplifier is substantially equal in magnitude for all of the signal line pairs of the signal line pair group. As an alternative, the position of each of the amplifiers in the amplifier group along the signal line direction is in each case chosen in such a way that the ratio which the interference signals coupled in on the first and the second signal line of a signal line pair assigned to the respective amplifier from their respectively adjacent lines have with respect to one another is substantially equal in magnitude for all of the signal line pairs of the signal line pair group. The improved coupling symmetry permits a reduction of the memory cell size and hence a higher integration density or alternatively a faster sensing time.

In a further embodiment it is provided that a control line is arranged in a manner adjoining a signal line pair wherein the respective signal line pair is assigned to an amplifier which is arranged substantially in the middle of the amplifier group extending in a signal line direction. Precisely control lines whose signals have high level swings can generate particularly strong interference signals on adjacent signal lines. Consequently, an unbalanced coupling in on the adjacent signal line pair can be reduced with the aid of this embodiment.

Further embodiments provide for the signal line pairs to form two mutually separate subgroups. Furthermore, it is provided that the amplifiers also form subgroups which are respectively assigned a dedicated select line. In this case, the signal line pairs of a signal line pair subgroup are respectively assigned only amplifiers of a single amplifier subgroup. This specific arrangement makes it possible to increase the probability that, in the case of a failure of two adjacent bit lines, instead of two now only one amplifier subgroup containing the relevant bit lines or bit line pairs must be replaced by redundant elements. The failure rate of an integrated circuit can thereby be reduced.

In accordance with a further embodiment, an amplifier subgroup respectively includes only directly adjacent amplifiers. The assignment of the common select line to the amplifier subgroup can be realized in a particularly simple manner with the aid of this arrangement.

One embodiment provides that a group of eight signal line pairs are assigned to a group of eight amplifiers arranged successively in a signal line direction, wherein the signal line pair group is delimited by two control lines running parallel to the signal line pairs, and forms two mutually shielded subgroups each having four signal line pairs. In this case, the first signal line pair is assigned to the fourth amplifier wherein the second signal line pair is assigned to the eighth amplifier, wherein the third signal line pair is assigned to the third amplifier, wherein the fourth signal line pair is assigned to the first amplifier, wherein the fifth signal line pair is assigned to the sixth amplifier, wherein the sixth signal line pair is assigned to the second amplifier, wherein the seventh signal line pair is assigned to the seventh amplifier, and wherein the eighth signal line pair is assigned to the fifth amplifier. With the aid of this specific arrangement it is possible to achieve a particularly fast sensing of the potential difference on the two signal lines of each signal line pair.

In a further embodiment it is provided that a group of eight signal line pairs are assigned to a group of eight amplifiers arranged successively in a signal line direction, wherein the signal line pair group is delimited by two control lines running parallel to the signal line pairs, and forms two mutually shielded subgroups each having four signal line pairs, wherein the first signal line pair is assigned to the fourth amplifier, the second signal line pair is assigned to the eighth amplifier, the third signal line pair is assigned to the second amplifier, the fourth signal line pair is assigned to the sixth amplifier, the fifth signal line pair is assigned to the third amplifier, the sixth signal line pair is assigned to the seventh amplifier, the seventh signal line pair is assigned to the first amplifier, and the eighth signal line pair is assigned to the fifth amplifier. With the aid of this specific arrangement it is possible to achieve an optimum signal gain and at the same time a fast sensing of the potential difference on the two signal lines of each signal line pair.

In a further embodiment it is provided that a group of eight signal line pairs are assigned to a group of eight amplifiers arranged successively in a signal line direction, wherein the signal line pair group is delimited by two control lines running parallel to the signal line pairs, and forms two mutually shielded subgroups each having four signal line pairs, wherein the first signal line pair is assigned to the fourth amplifier, wherein the second signal line pair is assigned to the third amplifier, the third signal line pair is assigned to the first amplifier, the fourth signal line pair is assigned to the second amplifier, the fifth signal line pair is assigned to the seventh amplifier, the sixth signal line pair is assigned to the eighth amplifier, the seventh signal line pair is assigned to the sixth amplifier, and the eighth signal line pair is assigned to the fifth amplifier. In the case of this specific arrangement, the amplifiers form two subgroups which are respectively assigned to a signal line pair subgroup. This reduces the probability that in the case of a failure of two adjacent signal line pairs, all the amplifiers of the amplifier group must be replaced by redundant elements. At the same time this arrangement permits a particularly fast sensing of the potential difference on the two signal lines of each signal line pair, which becomes apparent by virtue of a faster sensing time in the case of a memory circuit.

In a further embodiment it is provided that a group of eight signal line pairs are assigned to a group of eight amplifiers arranged successively in a signal line direction, wherein the signal line pair group is delimited by two control lines running parallel to the signal line pairs, and forms two mutually shielded subgroups each having four signal line pairs, wherein the first signal line pair is assigned to the fourth amplifier, the second signal line pair is assigned to the first amplifier, the third signal line pair is assigned to the third amplifier, the fourth signal line pair is assigned to the second amplifier, the fifth signal line pair is assigned to the seventh amplifier, the sixth signal line pair is assigned to the eighth amplifier, the seventh signal line pair is assigned to the sixth amplifier, and the eighth signal line pair is assigned to the fifth amplifier. In the case of this specific arrangement, too, the amplifiers form two subgroups respectively assigned to a signal line pair subgroup. This reduces the probability that in the case of a failure of two adjacent signal line pairs, all the amplifiers of the amplifier group must be replaced by redundant elements. Furthermore, this arrangement permits an optimum signal gain with at the same time a relatively fast sensing of the potential difference on the two signal lines of each signal line pair. In the case of a DRAM memory circuit, this leads to a reduction of the loss of signal on the bit line pair and thus to an increase in the signal margin.

Further embodiments will be described in conjunction with the accompanying drawings, whereby the same reference numerals refer to the same elements.

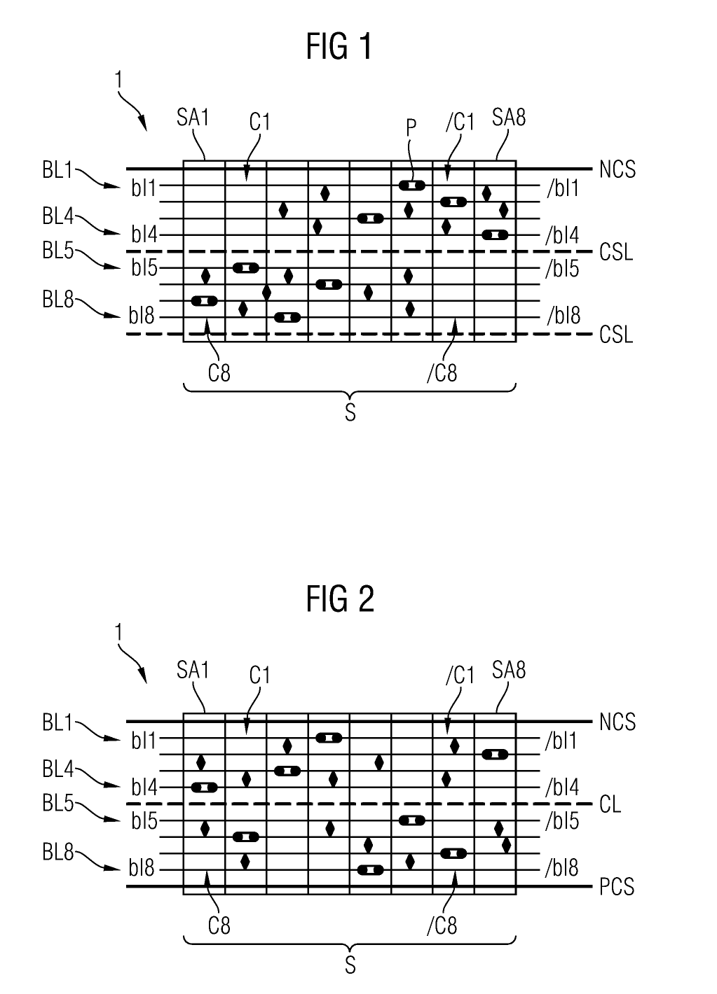

FIG. 1 illustrates an arrangement of in total 16 signal lines bl1, /bl1, bl2, /bl2, bl3, /bl3, bl4, /bl4, bl5, /bl5, bl6, /bl6, bl7, /bl7, bl8, /bl8 and eight associated amplifiers SA1-SA8. Such an arrangement occurs, e.g., in a memory device M, such as the dynamic random access memory (DRAM). Such a memory device M generally includes a multiplicity of memory cells arranged in a cell array. The cell array is pervaded by word and bit lines crossing one another in matrix form, wherein the memory cells are arranged respectively at the crossover points between the word and bit lines (memory cells and word lines are not illustrated in FIG. 1. The memory cells can be individually addressed with the aid of the word and bit lines. In the case of a DRAM memory, a word line switches a selection transistor of the selected memory cell, which transistor electrically connects the storage capacitor of the respective memory cell to the associated bit line bl. Via the bit line bl serving as a signal line, a specific charge is then read out from the memory cell or written to the memory cell. An amplifier circuit SA connected to the associated bit line, the sense amplifier, is used for reading from the memory cell. The amplifier SA detects a potential displacement brought about by the charge of the memory cell capacitor on the associated bit line bl. In order reliably to detect even tiny potential changes on the bit line bl, in this case, generally use is made of a differentially operating sense amplifier SA, which compares the electrical potential of the respective bit line bl with the electrical potential of a reference line /bl. In this case, another bit line, which is likewise connected to the respective sense amplifier SA, is regularly used as the reference line /bl. In FIG. 1 the sense amplifiers SA, illustrated as rectangles, extend over the entire bit line pair group B. The bit line pairs BL and the sense amplifiers SA lie in different planes, wherein a bit line bl and its reference bit line /bl are connected to a sense amplifier SA assigned to them in each case by using a dedicated contact P. The contacts P are likewise illustrated purely schematically in FIG. 1. A bit line bl and its reference bit line /bl together form a complementary bit line pair BL. In the open bit line architecture illustrated here, the bit line bl and its reference bit line /bl are arranged on both sides of the common sense amplifier SA.

The 16 signal lines bl1-bl8 and /bl1-/bl8 illustrated in FIG. 1 form eight complementary bit line pairs BL1-BL8 which are organized in a bit line pair group B. In this case, the bit line pairs BL1-BL8 of the bit line pair group B are assigned a group of in total eight sense amplifiers SA1-SA8. Within the bit line pair group B, the bit line pairs are combined in two subgroups B1, B2 each including four adjacent bit line pairs BL1-BL4 and BL5-BL8, which are separated from one another by a select line CSL running parallel to them. For reasons of clarity, not all of the bit lines bl, /bl, bit line pairs BL, sense amplifiers SA and coupling sections C, /C are provided with their own reference symbol in the figures. In order to illustrate the distribution of these structures within the respective arrangement, in each case only the first and the last bit line pair BL1, BL4, BL5, BL8 of the bit line pair group B or bit line pair subgroup B and in each case only the first and the last sense amplifier SA1, SA8 of the amplifier group S or the amplifier subgroup S1, S2 have a reference symbol. On account of the high integration density of modern DRAM memory circuits, the distance between the bit line pairs BL among one another and the distance between a bit line pair BL and an adjacent select or control line CSL, NCS, PCS is extremely small. This causes a high coupling susceptibility of the bit lines. This is fostered still further by the relatively long section over which the lines BL, CSL, NCS, PCS run alongside one another in the region of the sense amplifiers and in the cell array. Therefore, even relatively weak signals on the lines can cause disturbing interference signals. The coupling effects attributable to reciprocal influencing of the lines occur to a particularly great extent in the case of directly adjacent lines since, on the one hand, the capacitive coupling of two lines is greatly dependent on the distance between the relevant lines and, on the other hand, the metallic lines BL, CSL function as reciprocal shields. The capacitive coupling between in each case two directly adjacent bit lines bl, /bl is indicated schematically in FIG. 1 by small rhombi between the respective bit lines bl, /bl.

Since, in the case of a DRAM memory, two complementary bit lines bl, /bl of a bit line pair BL are pulled to different electrical potentials by the associated sense amplifier SA, the effect of the bit lines bl, /bl on the adjacent bit line pairs is generally asymmetrical. However, the reciprocal influencing proves particularly critical only in the case of bit line pairs whose read-out phases, i.e. signal formation and sensing phases, have a temporal overlap.

Besides coupling effects which are caused by a reciprocal influencing of the bit and control lines, coupling effects which are caused by adjacent circuit parts, such as e.g., by the sense amplifiers, on the bit lines can also prove to be particularly disturbing. When a sense amplifier SA is activated, relatively high signals can occur on the internal lines of the respective sense amplifier and can influence the electrical potential of the bit lines bl, /bl running directly above or below them. Since each sense amplifier SA of the sense amplifier group S arranged substantially in the bit line direction or along the bit lines bl, /bl is arranged symmetrically only relative to the bit line pair BL respectively assigned to it, the interference signals caused by the respective sense amplifier SA on the further bit line pairs BL of the group B typically do not occur symmetrically. If the sense amplifiers SA as is the case for the DRAM memory illustrated in FIG. 1, extend over a plurality of bit line pairs BL of the bit line pair group B, such that one bit line pair runs along a plurality of sense amplifiers, the instances of asymmetrical coupling-in of the different sense amplifiers SA can be superposed on one another. An unfavorable connection configuration between the sense amplifiers SA and the bit line pairs BL can easily have the effect that the interference signals caused by the sense amplifiers SA in the case of some bit line pairs BL of the bit line pair group B are coupled in substantially symmetrically or in a balanced manner, while on other bit line pairs BL the interference signals occur in particularly asymmetrical or unbalanced fashion. This variation of the coupling-in symmetry or coupling-in asymmetry within the bit line pair group B can have a very adverse effect on the performance of the entire memory device 2. This is because in order to ensure specific properties, such as e.g., the data integrity, the memory device must be designed and operated such that a satisfactory performance is possible for all of the bit line pairs BL. This necessarily presupposes, however, that the performance potential is not utilized optimally at least in some of the bit line pairs.

Since the previous circuit concept illustrated in FIG. 1 does not provide for taking account of the internal coupling in the region of the sense amplifiers, the signal consumption caused by coupling effects on specific bit line pairs is generally compensated for by an increased memory cell capacitance, which either reduces the production yield or requires a larger cell area.

In order to increase the performance of the entire memory device or the yield of the production process of the memory device or to achieve a higher integration density, the connection configuration between the bit line pairs and the sense amplifiers is to be optimized according to the embodiments below.

In the following FIGS. 2 to 5, four embodiments of the arrangement are described in more detail, in which embodiments the connection configuration between the bit line pairs and the assigned sense amplifiers was optimized in each case according to different criteria. The aim of such optimization is always to achieve an improvement in the performance of the entire memory. Therefore, it is expedient to use the criteria illustrated here for improving the coupling-in symmetry not only in the case of individual, but in the case of all bit line pairs BL of a group B. For this reason, the connection configurations illustrated here by way of example, are primarily optimized to the effect that the performance of the worst bit line pairs of the group B is improved and the desired properties (e.g., best sensing time or an optimum signal margin) are therefore distributed as homogeneously as possible over the entire bit line pair group B or else, depending on the respective application, over only part of the bit line pair group B.

Substantially, this is achieved by virtue of the fact that the connection configuration chosen limits the asymmetrical interference signal coupling-in on a bit line pair BL, for example, during the read-out operation. In one embodiment, the potential differences produced as a result of parasitic coupling effects on the two complementary bit lines bl, bl of a bit line pair BL during the read-out or sensing phase are reduced to an extent such that the potential difference produced between the respective bit line bl and its reference bit line /bl during the read-out of a memory cell information item cannot be corrupted.

What is responsible for coupling in interference signals on a bit line is the coupling section C, /C, which forms the respective bit line bl, /bl with the circuit parts adjacent to it. It determines the susceptibility of the bit line to interference signals. The strength with which the interference signals actually occur on the respective bit line and how critical they actually prove to be for the operation of the semiconductor circuit 2 depend in this case on the coupling properties of the coupling section C, /C. The coupling properties are primarily determined by the geometry of the bit line and, in one embodiment, by its length on which interference signals can couple in. In this case, that portion of the bit line over which the latter runs near to its neighboring lines or the circuit parts adjacent to it plays a crucial role. The distance between the bit line and the lines or circuit parts adjacent to it is also significant for the magnitude of the coupled-in interference signals and thus for the coupling properties of the coupling section. Furthermore, the signal strength on the adjacent conductor structures is also important for determining the extent to which the relevant conductor structures are responsible for the occurrence of interference signals on the bit line. Thus, e.g., a line whose signals have a relatively high level or level swing influences the adjacent bit line typically significantly more than an equivalent line having only a relatively low signal level or signal level swing. Furthermore, the coupling properties of a coupling section can also be determined by the signal profile on the respective bit line and the lines or circuit parts adjacent to it. Since coupled-in interference signals in the case of a DRAM memory have a particularly critical effect predominantly only during the read-out operation of a memory cell, i.e. during the signal formation and sensing phase on the respective bit line, signals of adjacent circuit parts which have no or only a negligibly small temporal overlap with the critical read-out or sensing phase of the respective bit line are not responsible for the occurrence of critical states. These signals or the respective circuit parts play no or only a negligible role in the determination of the coupling properties of the coupling section and, therefore, can be left out of consideration. Since the interference signal on each bit line is proportionally composed of the coupled-in interference signals of all the neighboring lines or neighboring circuit parts of the respective bit line, when determining the coupling properties of the coupling section of a bit line it is necessary to take into consideration all couplings between the respective bit line and the various lines or circuit parts.

In order to achieve a best possible coupling-in symmetry for a bit line pair BL, the coupling sections C, /C forming the two complementary bit lines bl, /bl of the respective bit line pair BL with their respectively adjacent conductor structures along the sense amplifier arrangement S substantially have the same coupling properties. In this case, the profile and the spacing of the lines or conductor structures involved and also their temporal signal developments have to be taken into consideration, inter alia, in the optimization. Furthermore, the reciprocal interdependence of the coupling sections C, /C of all the bit lines bl, /bl involved also have to be taken into consideration in the optimization of the coupling sections C, /C for a plurality of directly adjacent bit line pairs BL. This is because the assignment of a sense amplifier SA to a bit line pair BL always affects the relationship of the coupling sections of the adjacent bit line pairs and vice versa. On account of this reciprocal dependence of the coupling sections of adjacent bit lines, the process of finding an optimum connection configuration in an arrangement having a plurality of bit line pairs BL and associated sense amplifiers SA can prove, under certain circumstances, to be very complicated or computationally intensive especially as the reciprocal interactions of all the lines involved, if appropriate, have to be calculated for a multiplicity of possible connection permutations and operating situations and be compared with one another.

FIG. 2 illustrates a specific arrangement in which the connection scheme between the sense amplifiers and the bit line pairs was optimized with the aid of the method according to the embodiments. In this case, the position of the sense amplifiers SA within the sense amplifier arrangement S was in each case chosen in such a way that a particularly asymmetrical coupling in of interference signals on the respective bit line pair does not take place for any of the bit line pairs BL1-BL8 of the group B during the operation of the memory device and in one embodiment during the critical read-out or signal formation or sensing phase on a bit line pair. In this case, the assignment of the sense amplifiers was primarily optimized to the effect that all of the bit line pairs BL1-BL8 of the group B permit a best possible sensing time. Consequently, a DRAM memory having the arrangement illustrated in FIG. 1 is distinguished by a relatively small variation of the coupling-in asymmetry and also a particularly good sensing time.

As illustrated in FIG. 2, the first bit line pair BL1 of the bit line pair group B is connected to the fourth sense amplifier SA4, which is substantially arranged in the middle of the sense amplifier group S. What is achieved as a result of this is that the signals of the directly adjacent control line NCS couple in symmetrically on the two bit lines bl1, /bl1 of the first bit line pair BL1. For the same reason, the eighth bit line pair BL8 is connected to the fifth sense amplifier SA5 The second bit line pair BL2 is furthermore connected to the eighth sense amplifier SA8, the third bit line pair BL3 is connected to the third sense amplifier SA3, the fourth bit line pair BL4 is connected to the first sense amplifier SA1, the fifth bit line pair BL5 is connected to the sixth sense amplifier SA6, the sixth bit line pair BL6 is connected to the second sense amplifier SA6 and the seventh bit line pair BL7 is connected to the seventh sense amplifier SA7.

The line CL arranged between the two bit line pair groups B1, B2 can be a select line CSL, for example. While the two control lines NCS, PCS serve for the activation of the sense amplifiers SA of the sense amplifier group S and therefore experience a change in their electrical potential during the critical read-out or sensing phase of the bit line pairs BL, the line CL has a constant electrical potential during this time. This was correspondingly taken into consideration in the optimization of the connection configuration.

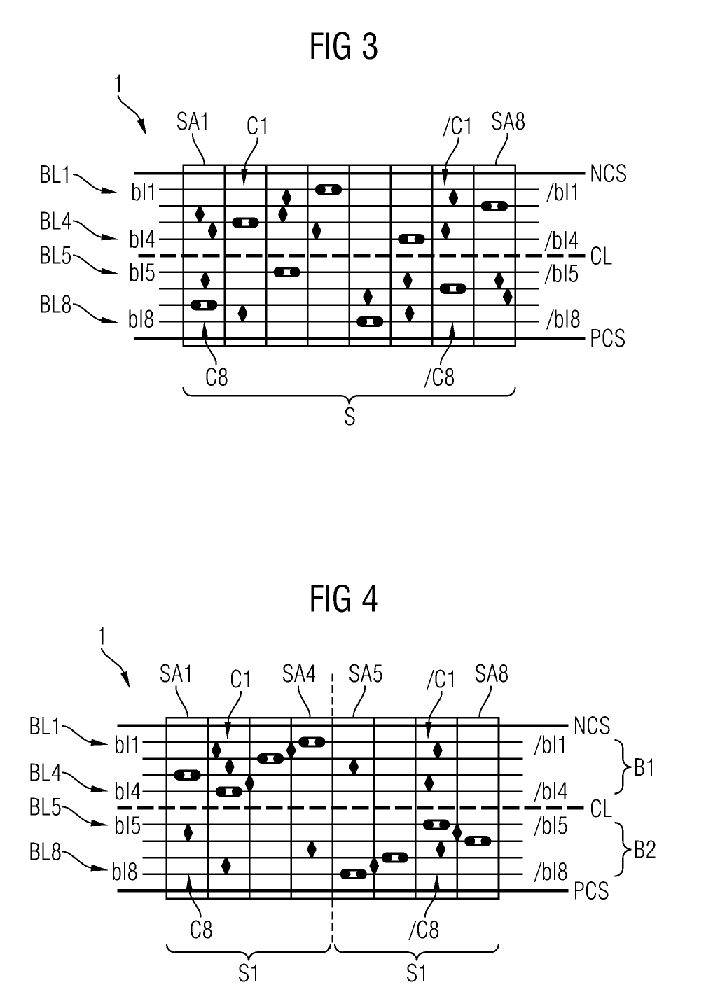

FIG. 3 illustrates a second arrangement with a further connection scheme between he bit line pairs and the associated sense amplifiers. With the aid of the method according to embodiments, the arrangement was in this case optimized in such a way that apart from a good sensing time, a reduction of the signal losses caused by coupling effects on the respective bit line pairs (best signal margin) was also achieved.

In this case, the two sense amplifiers SA4, SA5 assigned to the first and the eighth bit line pair BL1, BL8 have, analogously to the arrangement illustrated in FIG. 2, an substantially central position in the sense amplifier group S extending in the bit line direction. Furthermore, the second bit line pair BL2 is connected to the eighth sense amplifier SA8, the third bit line pair BL3 is connected to the second sense amplifier SA2, the fourth bit line pair BL4 is connected to the sixth sense amplifier SA6, the fifth bit line pair BL5 is connected to the third sense amplifier SA3, the sixth bit line pair BL6 is connected to the seventh sense amplifier SA7 and the seventh bit line pair BL7 is connected to the first sense amplifier SA1.

In the case of a DRAM memory, a plurality of sense amplifiers SA of a sense amplifier group S can be addressed jointly. Typically, therefore they are also assigned to a common select line CSL, which produces a connection between the global data path and the associated sense amplifiers. The sense amplifiers SA assigned to a select line CSL therefore belong logically to a common Y address. In the case of the arrangement illustrated here by way of example with a group S of in total eight sense amplifiers SA1-SA8 and associated bit line pairs BL1-BL8, generally in each case four sense amplifiers SA1-SA4, SA5-SA8 are assigned to a common select line CSL (Column Select Line). On account of the common addressing, in the case of a failure of a bit line assigned to a specific sense amplifier, in addition to the respective sense amplifier and the associated bit line, generally all the other sense amplifiers and bit lines assigned to the same select line CSL are also replaced by redundant elements. Since the association of the respective sense amplifiers SA and the bit lines with the select lines CSL is not taken into consideration in the assignment of the sense amplifiers SA to the bit line pairs BL in FIGS. 2 and 3, inter alia directly adjacent bit lines BL can also be connected to sense amplifiers SA which are not assigned to the same select line CSL. However, such an assignment may prove to be disadvantageous in specific cases. This is because in the case of a failure of two directly adjacent bit lines, there is the risk that straight away two select lines CSL must be replaced. Since contamination during the production process relatively frequently concerns two directly adjacent bit lines, this risk is relatively high.

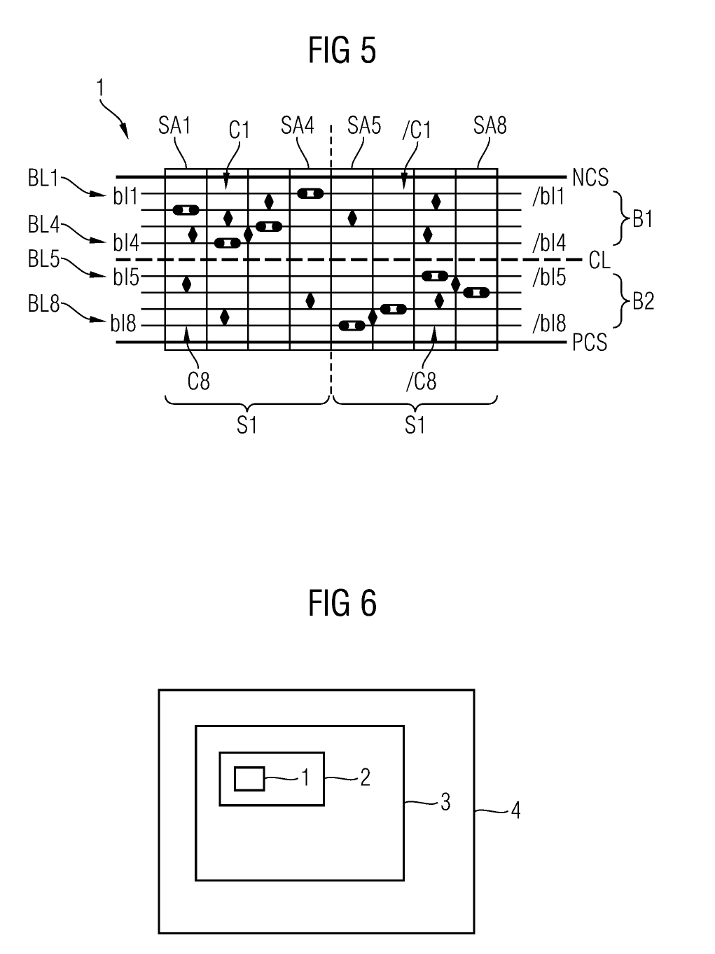

Therefore, it may be advantageous to connect directly adjacent bit line pairs BL only to sense amplifiers SA which are associated with the same select line CSL. In the case of a simultaneous failure of two adjacent bit lines BL, generally only one select line CSL then has to be replaced. This aspect was taken into consideration in the embodiments illustrated in the two following FIGS. 4 and 5. In this case, the first four sense amplifiers SA1, SA2, SA3, SA4 of the sense amplifier group S form a first subgroup S1, to which only bit line pairs BL1, BL2, BL3, BL4 of the upper bit line pair subgroup B1 are assigned. By contrast, the last four sense amplifiers SA5, SA6, SA7, SA8 of the sense amplifier group S, which together form a second subgroup S2, are only assigned bit line pairs BL5, BL6, BL7, BL8 of the lower bit line pair subgroup B2.

In this case, in FIG. 4, the first bit line pair BL1, which is directly adjacent to the upper control line NCS, analogously to the previous embodiments, is assigned to the fourth sense amplifier SA4, which is substantially arranged in the middle of the sense amplifier group S. The assignment of the further bit line pairs and sense amplifiers is chosen in such a way that the second bit line pair BL2 is connected to the third sense amplifier SA3, the third bit line pair BL3 is connected to the first sense amplifier SA1 and the fourth bit line pair BL4 is connected to the second sense amplifier SA2. In the second bit line pair subgroup B2, too, the eighth bit line pair BL8, which is directly adjacent to the lower control line PCS, analogously to the arrangements illustrated in the previous figures, is assigned to the fifth sense amplifier SA5, which is likewise substantially arranged in the middle of the sense amplifier group S. By contrast, the further bit line pairs of the lower bit line pair subgroup B2 are assigned to the remaining sense amplifiers in such a way that the fifth bit line pair BL5 is connected to the seventh sense amplifier SA7, the sixth bit line pair BL6 is connected to the eighth sense amplifier SA8 and the seventh bit line pair BL7 is connected to the sixth sense amplifier SA6.

Analogously to FIG. 4, FIG. 5 also illustrates a connection configuration in which directly adjacent bit line pairs BL are connected to sense amplifiers SA which are assigned to the same select line CSL. However, the connection configuration illustrated in FIG. 5 has been optimized such that a particularly good signal gain is possible.

In the embodiment as illustrated in FIG. 5, too, the first bit line pair BL1, which is directly adjacent to the upper control line NCS, analogously to the arrangements illustrated in the previous figures, is assigned to the fourth sense amplifier SA4. Furthermore, the assignment of the further bit line pairs and sense amplifiers is chosen in such a way that the second bit line pair BL2 is connected to the first sense amplifier SA1, the third bit line pair BL3 is connected to the third sense amplifier SA3 and the fourth bit line pair BL4 is connected to the second sense amplifier SA2. Finally, in the second bit line pair subgroup B2, too, the eighth bit line pair BL8, which is directly adjacent to the lower control line PCS, analogously to the arrangements illustrated in the previous figures, is connected to the fifth sense amplifier SA5 having a central position. Furthermore, the further bit line pairs and sense amplifiers are assigned to one another in such a way that the fifth bit line pair BL5 is connected to the seventh sense amplifier SA7, the sixth bit line pair BL6 is connected to the eighth sense amplifier SA8 and the seventh bit line pair BL7 is connected to the sixth sense amplifier SA6.

The signal margin gain which can be achieved by the connection configuration optimization according to embodiments as illustrated by way of example in the previous figures may perfectly well amount to 10% or more. To put it another way, the memory cell capacitance can be reduced by approximately 10% without losses of yield being expected during production. As a result, the optimization of the connection configuration enables a reduction of the production costs or an improvement in the integration capability for a specific memory cell concept. As explained in the above description, the coupling properties of the bit line pairs BL depend on various parameters such as e.g., the signal level or the temporal signal profile on a neighboring line. In principle this opens up the possibility, during the optimization of the connection configuration, of also performing an adaptation of the parameters, e.g., by choosing a different, more favorable order of access to adjacent bit line pairs BL.

FIG. 6 schematically illustrates a system 4 including the arrangement according to embodiments, which system may be formed for example as a computer system or some other electronic system such as, for example, a telephone, a camera or a PDA. In this case, the arrangement 1 according to the embodiment can be part of a memory device 2 arranged on a circuit board 3, e.g., on a motherboard of the computer system 4. The circuit board 3 can also be formed as a module that can be plugged on the motherboard (not illustrated here). The use of the arrangement 1 according to the embodiment within a computer system 4 is not restricted just to a DRAM memory device 2. Rather it can also be realized in other memory devices. Moreover, the connection configurations according to the embodiment as illustrated in the description above, the claims and the drawings on the basis of a memory device can, in principle, also be applied to other integrated circuits in which a corresponding signal line pair group is connected to a corresponding amplifier group in the manner illustrated here.

The embodiments described in conjunction with the drawings are examples. Moreover, further coupling-optimized connection configuration of signal lines and amplifiers may be realized. These may include further modifications and combinations of the described arrangements and methods.

The preceding description describes embodiments. The features disclosed therein and the claims and the drawings can, therefore, be useful for realizing the invention in its various embodiments, both individually and in any combination. While the foregoing is directed to embodiments, other and further embodiments may be devised without departing from the basic scope of the invention, the scope of the present invention being determined by the claims that follow.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. An arrangement of signal line pairs and amplifiers,
wherein each signal line pair of a group of signal line pairs running alongside one another is respectively assigned an amplifier from a group of amplifiers arranged in a signal line direction, the amplifier extending perpendicular to the signal line direction over a plurality of signal line pairs of the signal line pair group;
wherein each signal line pair comprises a first and a second signal line, between which the amplifier assigned to the respective signal line pair is arranged, wherein the amplifier amplifies a difference in the electrical potentials on the two signal lines; and
wherein the position of an amplifier assigned to a specific signal line pair in the amplifier group along the signal line direction is chosen in such a way that a first coupling section which forms the first signal line assigned to the respective amplifier together with its adjacent lines along the amplifier group, and a second coupling section, which forms the second signal line assigned to the respective amplifier together with its adjacent lines along the amplifier group, substantially have the same coupling properties.

2. The arrangement as claimed in claim 1, wherein the position of each of the amplifiers in the amplifier group along the signal line direction is chosen in such a way that the degree of deviation between the coupling properties of the first and the second coupling sections of a signal line pair assigned to an amplifier is substantially equal in magnitude for all of the signal line pairs of the signal line pair group.

3. The arrangement as claimed in claim 1, wherein the position of each amplifier in the amplifier group along the signal line direction is in each case chosen in such a way that the ratio which the interference signals coupled in on the first and the second signal line assigned to an amplifier from their respectively adjacent lines have with respect to one another is substantially equal in magnitude for all of the signal line pairs of the signal line pair group.

4. The arrangement as claimed in claim 1,
wherein a control line is arranged in a manner adjoining a signal line pair; and
wherein the respective signal line pair is assigned to an amplifier which is arranged substantially in the middle of the amplifier group extending in a signal line direction.

5. The arrangement as claimed in claim 1,
wherein respectively directly adjacent signal line pairs form two mutually separate signal line pair subgroups;
wherein the amplifiers form amplifier subgroups, wherein the amplifier subgroups are respectively assigned a dedicated select line;
wherein the signal line pairs of a signal line pair subgroup are respectively assigned only amplifiers of a single amplifier subgroup; and
wherein an amplifier subgroup respectively comprises only directly adjacent amplifiers.

6. The arrangement as claimed in claim 1,
wherein a group of eight signal line pairs are assigned to a group of eight amplifiers arranged successively in a signal line direction;
wherein the signal line pair group is delimited by two control lines running parallel to the signal line pairs, and forms two signal line pair subgroups each having four signal line pairs;
wherein the first signal line pair is assigned to the fourth amplifier;
wherein the second signal line pair is assigned to the eighth amplifier;
wherein the third signal line pair is assigned to the third amplifier;
wherein the fourth signal line pair is assigned to the first amplifier;
wherein the fifth signal line pair is assigned to the sixth amplifier;
wherein the sixth signal line pair is assigned to the second amplifier;
wherein the seventh signal line pair is assigned to the seventh amplifier; and
wherein the eighth signal line pair is assigned to the fifth amplifier.

7. The arrangement as claimed in claim 1,
wherein a group of eight signal line pairs are assigned to a group of eight amplifiers arranged successively in a signal line direction;
wherein the signal line pair group is delimited by two control lines running parallel to the signal line pairs, and forms two signal line pair subgroups each having four signal line pairs;
wherein the first signal line pair is assigned to the fourth amplifier;
wherein the second signal line pair is assigned to the eighth amplifier;
wherein the third signal line pair is assigned to the second amplifier;
wherein the fourth signal line pair is assigned to the sixth amplifier;
wherein the fifth signal line pair is assigned to the third amplifier;
wherein the sixth signal line pair is assigned to the seventh amplifier;
wherein the seventh signal line pair is assigned to the first amplifier; and
wherein the eighth signal line pair is assigned to the fifth amplifier.

8. The arrangement as claimed in claim 1,
wherein a group of eight signal line pairs are assigned to a group of eight amplifiers arranged successively in a signal line direction;
wherein the signal line pair group is delimited by two control lines running parallel to the signal line pairs, and forms two signal line pair subgroups each having four signal line pairs;
wherein the first signal line pair is assigned to the fourth amplifier;
wherein the second signal line pair is assigned to the third amplifier;
wherein the third signal line pair is assigned to the first amplifier;
wherein the fourth signal line pair is assigned to the second amplifier;
wherein the fifth signal line pair is assigned to the seventh amplifier;
wherein the sixth signal line pair is assigned to the eighth amplifier;
wherein the seventh signal line pair is assigned to the sixth amplifier; and
wherein the eighth signal line pair is assigned to the fifth amplifier.

9. The arrangement as claimed in claim 1,
wherein a group of eight signal line pairs are assigned to a group of eight amplifiers arranged successively in a signal line direction;
wherein the signal line pair group is delimited by two control lines running parallel to the signal line pairs, and forms two signal line pair subgroups each having four signal line pairs;
wherein the first signal line pair is assigned to the fourth amplifier;
wherein the second signal line pair is assigned to the first amplifier;
wherein the third signal line pair is assigned to the third amplifier;
wherein the fourth signal line pair is assigned to the second amplifier;
wherein the fifth signal line pair is assigned to the seventh amplifier;
wherein the sixth signal line pair is assigned to the eighth amplifier;
wherein the seventh signal line pair is assigned to the sixth amplifier; and
wherein the eighth signal line pair is assigned to the fifth amplifier.

10. An integrated circuit comprising an arrangement of signal line pairs and amplifiers,
wherein each signal line pair of a group of signal line pairs running alongside one another is respectively assigned an amplifier from a group of amplifiers arranged in a signal line direction, the amplifier extending perpendicular to the signal line direction over a plurality of signal line pairs of the signal line pair group,
wherein each signal line pair comprises a first and a second signal line, between which the amplifier assigned to the respective signal line pair is arranged, wherein the amplifier amplifies a difference in the electrical potentials on the two signal lines, and
wherein the position of an amplifier assigned to a specific signal line pair in the amplifier group along the signal line direction is chosen in such a way that a first coupling section which forms the first signal line assigned to the respective amplifier together with its adjacent lines along the amplifier group, and a second coupling section, which forms the second signal line assigned to the respective amplifier together with its adjacent lines along the amplifier group, substantially have the same coupling properties.

11. The integrated circuit as claimed in claim 10,
wherein the position of each of the amplifiers in the amplifier group along the signal line direction is chosen in such a way
that the degree of deviation between the coupling properties of the first and the second coupling sections of a signal line pair assigned to an amplifier is substantially equal in magnitude for all of the signal line pairs of the signal line pair group.

12. The integrated circuit as claimed in claim 10,
wherein the position of each amplifier in the amplifier group along the signal line direction is in each case chosen in such a way
that the ratio which the interference signals coupled in on the first and the second signal line assigned to an amplifier from their respectively adjacent lines have with respect to one another is substantially equal in magnitude for all of the signal line pairs of the signal line pair group.

13. The integrated circuit as claimed in claim 10,
wherein a control line is arranged in a manner adjoining a signal line pair,
wherein the respective signal line pair is assigned to an amplifier which is arranged substantially in the middle of the amplifier group extending in a signal line direction.

14. The integrated circuit as claimed in claim 10,
wherein respectively directly adjacent signal line pairs form two mutually separate signal line pair subgroups;
wherein the amplifiers form amplifier subgroups, the amplifier subgroups being respectively assigned a dedicated select line;
wherein the signal line pairs of a signal line pair subgroup are respectively assigned only amplifiers of a single amplifier subgroup; and
wherein an amplifier subgroup respectively comprises only directly adjacent amplifiers.

15. The integrated circuit as claimed in claim 10,
wherein a group of eight signal line pairs are assigned to a group of eight amplifiers arranged successively in a signal line direction;
wherein the signal line pair group is delimited by two control lines running parallel to the signal line pairs, and forms two signal line pair subgroups each having four signal line pairs;
wherein the first signal line pair is assigned to the fourth amplifier;
wherein the second signal line pair is assigned to the eighth amplifier;
wherein the third signal line pair is assigned to the third amplifier;
wherein the fourth signal line pair is assigned to the first amplifier;
wherein the fifth signal line pair is assigned to the sixth amplifier;
wherein the sixth signal line pair is assigned to the second amplifier;
wherein the seventh signal line pair is assigned to the seventh amplifier; and
wherein the eighth signal line pair is assigned to the fifth amplifier.

16. The integrated circuit as claimed in claim 10,
wherein a group of eight signal line pairs are assigned to a group of eight amplifiers arranged successively in a signal line direction;
wherein the signal line pair group is delimited by two control lines running parallel to the signal line pairs, and forms two signal line pair subgroups each having four signal line pairs;
wherein the first signal line pair is assigned to the fourth amplifier;
wherein the second signal line pair is assigned to the eighth amplifier;
wherein the third signal line pair is assigned to the second amplifier;
wherein the fourth signal line pair is assigned to the sixth amplifier;
wherein the fifth signal line pair is assigned to the third amplifier;
wherein the sixth signal line pair is assigned to the seventh amplifier;
wherein the seventh signal line pair is assigned to the first amplifier; and
wherein the eighth signal line pair is assigned to the fifth amplifier.

17. The integrated circuit as claimed in claim 10,
wherein a group of eight signal line pairs are assigned to a group of eight amplifiers arranged successively in a signal line direction;
wherein the signal line pair group is delimited by two control lines running parallel to the signal line pairs, and forms two signal line pair subgroups each having four signal line pairs;
wherein the first signal line pair is assigned to the fourth amplifier;
wherein the second signal line pair is assigned to the third amplifier;
wherein the third signal line pair is assigned to the first amplifier;
wherein the fourth signal line pair is assigned to the second amplifier;
wherein the fifth signal line pair is assigned to the seventh amplifier;
wherein the sixth signal line pair is assigned to the eighth amplifier;
wherein the seventh signal line pair is assigned to the sixth amplifier; and
wherein the eighth signal line pair is assigned to the fifth amplifier.

18. The integrated circuit as claimed in claim 10,
wherein a group of eight signal line pairs are assigned to a group of eight amplifiers arranged successively in a signal line direction;
wherein the signal line pair group is delimited by two control lines running parallel to the signal line pairs, and forms two signal line pair subgroups each having four signal line pairs;
wherein the first signal line pair is assigned to the fourth amplifier;
wherein the second signal line pair is assigned to the first amplifier;
wherein the third signal line pair is assigned to the third amplifier;
wherein the fourth signal line pair is assigned to the second amplifier;
wherein the fifth signal line pair is assigned to the seventh amplifier;
wherein the sixth signal line pair is assigned to the eighth amplifier;
wherein the seventh signal line pair is assigned to the sixth amplifier; and
wherein the eighth signal line pair is assigned to the fifth amplifier.

19. The integrated circuit as claimed in claim 10,
wherein the integrated circuit is formed as a memory device having an open bit line architecture; and
wherein the signal lines of a signal line pair are formed as mutually complementary bit lines between which a respective sense amplifier is arranged.

20. A circuit board comprising at least one integrated circuit, the integrated circuit comprising an arrangement of signal line pairs and amplifiers,
wherein each signal line pair of a group of signal line pairs running alongside one another is respectively assigned an amplifier from a group of amplifiers arranged in a signal line direction, the amplifier extending perpendicular to the signal line direction over a plurality of signal line pairs of the signal line pair group;
wherein each signal line pair comprises a first and a second signal line, between which the amplifier assigned to the respective signal line pair is arranged, wherein the amplifier amplifies a difference in the electrical potentials on the two signal lines; and
wherein the position of an amplifier assigned to a specific signal line pair in the amplifier group along the signal line direction is chosen in such a way that a first coupling section which forms the first signal line assigned to the respective amplifier together with its adjacent lines along the amplifier group, and a second coupling section, which forms the second signal line assigned to the respective amplifier together with its adjacent lines along the amplifier group, substantially have the same coupling properties.

21. A computer system comprising a circuit board, the circuit board comprising at least one integrated circuit, the integrated circuit comprising an arrangement of signal line pairs and amplifiers,
wherein each signal line pair of a group of signal line pairs running alongside one another is respectively assigned an amplifier from a group of amplifiers arranged in a signal line direction, the amplifier extending perpendicular to the signal line direction over a plurality of signal line pairs of the signal line pair group;
wherein each signal line pair comprises a first and a second signal line, between which the amplifier assigned to the respective signal line pair is arranged, wherein the amplifier amplifies a difference in the electrical potentials on the two signal lines; and
wherein the position of an amplifier assigned to a specific signal line pair in the amplifier group along the signal line direction is chosen in such a way that a first coupling section which forms the first signal line assigned to the respective amplifier together with its adjacent lines along the amplifier group, and a second coupling section, which forms the second signal line assigned to the respective amplifier together with its adjacent lines along the amplifier group, substantially have the same coupling properties.

22. A method for optimizing a connection scheme of an arrangement of signal line pairs and assigned amplifiers, in which each signal line pair of a group of signal line pairs running alongside one another is respectively assigned an amplifier from a group of amplifiers arranged in a signal line direction, in order to amplify a difference in the electrical potentials on a first and a second signal line of the respective signal line pair,
wherein the amplifier is arranged between the two signal lines of the respective signal line pair, the method comprising:
choosing the position of the amplifier in the amplifier group along the signal line direction in such a way that a first coupling section which forms the first signal line assigned to the respective amplifier together with its adjacent lines along the amplifier group, and a second coupling section, which forms the second signal line assigned to the respective amplifier together with its adjacent lines along the amplifier group, substantially have the same coupling properties.

23. The method as claimed in claim 22,
wherein the position of each of the amplifiers in the amplifier group along the signal line direction is chosen in such a way that the degree of deviation between the coupling properties of the first and the second coupling sections of a signal line pair assigned to an amplifier is substantially equal in magnitude for all of the signal line pairs of the signal line pair group.

24. The method as claimed in claim 22,
wherein the position of each amplifier in the amplifier group along the signal line direction is in each case chosen in such a way that the ratio which the interference signals coupled in on the first and the second signal line assigned to an amplifier from their respectively adjacent lines have with respect to one another is substantially equal in magnitude for all of the signal line pairs of the signal line pair group.

25. The method as claimed in claim 22,
wherein a control line is arranged in a manner adjoining a signal line pair,
wherein the respective signal line pair is assigned to an amplifier which is arranged substantially in the middle of the amplifier group extending in a signal line direction;
wherein respectively directly adjacent signal line pairs form two mutually separate signal line pair subgroups;
wherein the amplifiers form amplifier subgroups, wherein the amplifier subgroups are respectively assigned a dedicated select line; and
wherein the signal line pairs of a signal line pair subgroup are respectively assigned only amplifiers of a single amplifier subgroup.
